(19) United States
(12) Patent Application Publication
(10) Pub. No.: US 2008/0067669 A1
(43) Pub. Date: Mar. 20, 2008

(54) Systems, devices and methods for controlling thermal interface thickness in a semiconductor die package

(76) Inventor: Nicole A. Buttel, Fort Collins, CO (US)

Correspondence Address: Kathy Manke;Avago Technologies Limited, 4380 Ziegler Road, Fort Collins, CO, 80525, US

(21) Appl. No.: 11/522,759

(22) Filed: Sep. 18, 2006

(51) Int. Cl. H01L 23/34

(52) U.S. Cl. 257/706

(57) ABSTRACT

Disclosed are various embodiments of systems, devices and methods for controlling the thickness of a thermal interface layer in a semiconductor die package. In one embodiment, spherical inclusions of at least a first substantially uniform diameter are suspended in a thermal material, which is then dispensed or metered onto the top surface of a semiconductor die. A heat spreading lid is then placed atop the metered or dispensed mixture of thermal material and spherical inclusions, and a mechanical load applied thereto. The load squeezes the thermal material between the lid and the die until the spherical inclusions of the first diameter form a layer of like-diameter spheres having upper and lower portions which contact the lower surface of the lid and the upper surface of the die, respectively. Accordingly, the spherical inclusions of the first diameter dictate the thickness of the thermal interface layer between the lid and the die in a highly controllable manner, resulting in a semiconductor die package that is easy to manufacture and yet possesses highly accurate mechanical dimensions, low stress and that has highly predictable thermal behavior between manufacturing lots.

### FIELD OF THE INVENTION

The present invention relates to the field of thermal interfaces and materials positioned between semiconductor dies and lids in semiconductor die packages.

### BACKGROUND

Semiconductor die packages comprising a flip chip, a lid acting as a thermal sink positioned atop the die, and a substrate to which the die is attached are known. Typically, the lid is attached to the underlying die by means of a thermal material, gel, solder or other suitable material. This material plays a critical role in transferring heat generated by the die to the lid, which may then spread or conduct the heat to other elements such as a heat sink. Heat removal becomes a challenge as die power consumption, die size and heat density increase with every new generation of semiconductor devices.

Unfortunately, many thermal interface materials possess poor thermal conductivity, resulting in less-than-optimal heat transfer rates. Additionally, as semiconductor die packages become ever smaller, accurate positioning and co-planarity of the lid and the underlying semiconductor die become ever more important. When dispensed or placed between a semiconductor die and a lid and thereafter cured or dried, however, many known thermal interface materials result in thermal interface layers of uneven thickness, tilting between the respective planes defined by the lid and the top surface of the die, and undesired stress concentrations between the lid and the die.

What is needed is a thermal interface material that is easy and inexpensive to apply, results in a thermal interface gap of uniform, predictable thickness and thermal behavior, produces a co-planar lid and underlying semiconductor die, and evenly distributes stresses between the lid and the die.

Various patents containing subject matter relating directly or indirectly to the field of the present invention include, but are not limited to, the following:

U.S. Pat. No. 3,905,037 to Bean et al. for “Integrated circuit components in insulated islands of integrated semiconductor materials in a single substrate,” Sep. 9, 1975.

U.S. Pat. No. 5,552,635 to Kim et al. for High thermal emissive semiconductor device package,” Sep. 3, 1996.

U.S. Pat. No. 5,587,882 to Patel for “Thermal interface for a heat sink and a plurality of integrated circuits mounted on a substrate,” Dec. 24, 1996.

U.S. Pat. No. 6,162,663 to Schoenstein et al. for “Dissipation of heat from a circuit board having bare silicon chips mounted thereon,” Dec. 19, 2000

U.S. Pat. No. 6,218,730 to Toy et al. for “Apparatus for controlling thermal interface gap distance,” Apr. 17, 2001.

U.S. Pat. No. 6,294,408 to Edwards et al. for “Method for controlling thermal interface gap distance,” Sep. 25, 2001.

U.S. Pat. No. 6,317,326 to Vogel et al. for “Integrated circuit device package and heat dissipation device,” Nov. 13, 2001.

U.S. Pat. No. 6,403,882 to Chen et al. for “Protective cover plate for flip chip assembly backside,” Jun. 11, 2002.

U.S. Pat. No. 6,617,683 to Lebonheur for “Thermal performance in flip chip/integral heat spreader packages using low modulus thermal interface material,” Sep. 9, 2003.

U.S. Pat. No. 6,744,132 to Alcoe et al. for “Module with thermal materially attached heat sink,” Jun. 1, 2004.

U.S. Pat. No. 6,773,963 to Houle for “Apparatus and method for containing excess thermal interface material,” Aug. 10, 2004.

U.S. Pat. No. 6,784,535 to Chiu for “Composite lid for land grid array (LGA) flip-chip package assembly,” Aug. 31, 2004.

U.S. Pat. No. 6,882,041 to Cheah et al. for “Thermally enhanced metal capped BGA package,” Apr. 19, 2005.

U.S. Pat. No. 6,896,045 to Panek for “Structure and method of attaching a heat transfer part having a compressible interface,” May 24, 2005.

U.S. Pat. No. 6,919,630 to Hsiao for “Semiconductor package with heat spreader,” Jul. 19, 2005.

U.S. Pat. No. 6,936,919 to Chuang et al. for “Heatsink-substrate-spacer structure for an integrated-circuit package,” Aug. 30, 2005.

U.S. Pat. No. 6,946,742 to Karpman for “Packaged microchip with isolator having selected modulus of elasticity,” Sep. 20, 2005.

U.S. Pat. No. 6,949,404 to Fritz et al. for “Flip chip package with warpage control,” Sep. 27, 2005.

U.S. Pat. No. 6,977,818 to Depew for “Heat dissipating device for an integrated circuit chip,” Dec. 20, 2005.

U.S. Pat. No. 7,009,307 to Li for “Low stress and warpage laminate flip chip BGA package,” Mar. 7, 2006.

The dates of the foregoing publications may correspond to any one of priority dates, filing dates, publication dates and issue dates. Listing of the above patents and patent applications in this background section is not, and shall not be construed as, an admission by the applicants or their counsel that one or more publications from the above list constitutes prior art in respect of the applicant's various inventions. All printed publications and patents referenced herein are hereby incorporated by referenced herein, each in its respective entirety.

Upon having read and understood the Summary, Detailed Descriptions and Claims set forth below, those skilled in the art will appreciate that at least some of the systems, devices, components and methods disclosed in the printed publications listed herein may be modified advantageously in accordance with the teachings of the various embodiments of the present invention.

### SUMMARY

Disclosed herein are various embodiments of systems, devices and methods for controlling the thickness of a thermal interface layer in a semiconductor die package.

In one embodiment of the present invention, spherical inclusions of at least a first substantially uniform diameter are suspended in an appropriate thermal material, which is then dispensed or metered onto the top surface of a semiconductor die. A heat spreading lid is then placed atop the metered or dispensed mixture of thermal material and spherical inclusions, and a mechanical load applied thereto. The load squeezes the thermal material between the lid and the die until the spherical inclusions of the first diameter form a layer of like-diameter spheres having upper and lower portions which contact the lower surface of the lid and the upper surface of the die, respectively. Accordingly, the spherical inclusions of the first diameter dictate the thickness of the thermal interface layer between the lid and the die in a highly controllable manner, resulting in a semiconductor die package that is easy to manufacture and yet possesses highly accurate mechanical dimensions, low stress and that has highly predictable thermal behavior between manufacturing lots.

In one embodiment of the present invention, there is provided a semiconductor die package comprising a semiconductor die, a lid covering at least portions of the die, and a thermal material disposed between the die and the lid. The thermal material comprises spherical inclusions of at least one substantially uniform diameter, where the inclusions form a layer of first diameter spheres between the die and the lid, and the inclusions and the thermal material form a thermal interface layer having a thickness corresponding to the first diameter. The package may further comprise a substrate upon which the semiconductor die is mounted. The lid, thermal material and the inclusions are preferably configured to conduct heat away from the semiconductor die. The thermal material preferably comprises epoxy, high-temperature epoxy, an adhesive, plastic, foam, a cured thermal material, a gel, a polymer gel, a crosslinked gel, a polymer or a crosslinked polymer. The spherical inclusions may comprise glass, silicon, ceramic, a metal, a metal alloy, silver, gold, copper, a polymer, a polymeric substance or a plastic. The spherical inclusions may have diameters ranging between about 25 microns and about 75 microns, and the thickness of the thermal interface layer may also range between about 25 microns and about 75 microns.

In another embodiment of the present invention, there is provided a method of making a semiconductor die package comprising assembling a semiconductor die and a lid with a thermal material having spherical inclusions of at least a first substantially uniform diameter disposed therebetween. The method may further comprise curing the thermal material, cross-linking the thermal material, compressing the thermal material and the inclusions between the lid and the die, compressing the thermal material and the inclusions between the lid and the die until at least some of the inclusions engage both the lid and the die, mounting the semiconductor die on a substrate, and mounting a heat sink to the lid.

In yet another embodiment of the present invention, there is provided a method of dissipating heat from a semiconductor die package comprising transferring heat from a semiconductor die in a semiconductor die package to a lid in the package with a thermal interface layer disposed between the semiconductor die and the lid, where the thermal interface layer comprises spherical inclusions of at least a first substantially uniform diameter and the inclusions form a layer of first-diameter spheres between the die and the lid.

In addition to the foregoing embodiments of the present invention, review of the detailed description and accompanying drawings will show that other embodiments of the present invention exist. Accordingly, many combinations, permutations, variations and modifications of the foregoing embodiments of the present invention not set forth explicitly herein will nevertheless fall within the scope of the present invention.

### BRIEF DESCRIPTION OF THE DRAWINGS

Different aspects of the various embodiments of the present invention will become apparent from the following specification, drawings and claims in which:

FIG. 1 shows a cross-sectional view of a semiconductor die package made in accordance with one embodiment of the present invention;

FIG. 2 shows a close-up view of a portion of the semiconductor die package of FIG. 1 according to one embodiment of the present invention;

FIG. 3 shows a close-up view of a portion of the semiconductor die package of FIG. 1 according to another embodiment of the present invention;

FIG. 4 shows a close-up view of a portion of the semiconductor die package of FIG. 1 according to yet another embodiment of the present invention;

FIG. 5 illustrates a method according to one embodiment of the present invention.

The drawings are not necessarily to scale. Like numbers refer to like parts or steps throughout the drawings.

### DETAILED DESCRIPTIONS

Set forth below are detailed descriptions of some preferred embodiments of the systems, devices and methods of the present invention. Disclosed herein are various embodiments of systems, devices and methods for controlling the thickness of a thermal interface layer in a semiconductor die package.

In one embodiment of the present invention, spherical inclusions of at least a first substantially uniform diameter are suspended in a thermal material, which is then dispensed or metered onto the top surface of a semiconductor die. A heat spreading lid is then placed atop the metered or dispensed mixture of thermal material and spherical inclusions, and a mechanical load applied thereto. The load squeezes the thermal material between the lid and the die until the spherical inclusions of the first diameter form a layer of like-diameter spheres having upper and lower portions which contact the lower surface of the lid and the upper surface of the die, respectively. Accordingly, the spherical inclusions of the first diameter dictate the thickness of the thermal interface layer between the lid and the die in a highly controllable manner, resulting in a semiconductor die package that is easy to manufacture and yet possesses highly accurate mechanical dimensions, low stress and that is characterized in having highly predictable thermal behavior between manufacturing lots.

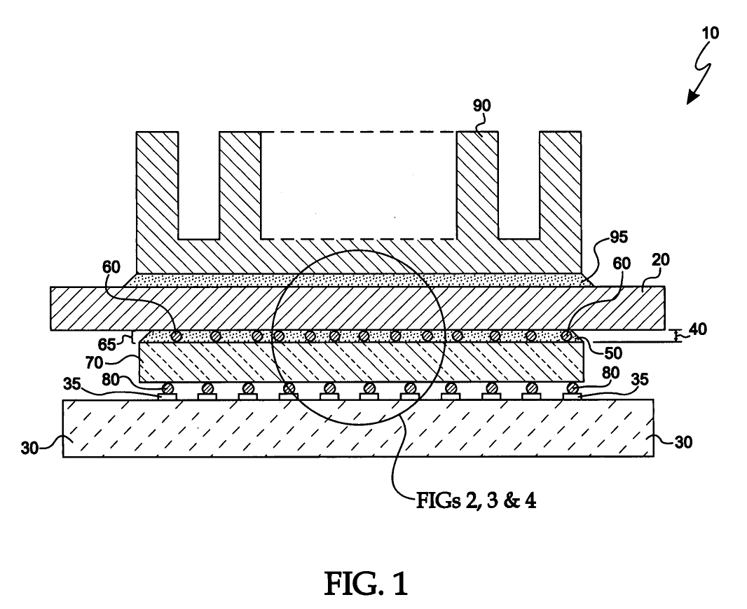

FIG. 1 shows a cross-sectional view of semiconductor die package 10 made in accordance with one embodiment of the present invention. Semiconductor die 70 is preferably mounted on ceramic substrate 30 by means of solder balls 80, which engage substrate pads 35. Substrate 30 need not be formed of ceramic, however, but may be a Surface Laminar Circuit (“SLC”)™, a printed circuit board, have a surface suitable for wire bonding, or be formed from a suitable organic material. Semiconductor die 70 is positioned between substrate 30 and lid 20 for environmental and handling protection. Some examples of devices that semiconductor die 10 may comprise include, but are not limited to, a central processing unit, a microprocessor, an ASIC, a controller and a processor.

Lid 20 covers and protects die 70 and also serves as a thermal sink for heat conducted thereto via thermal interface material 50 and spherical inclusions 60, more about which is said below. Optional heat sink 90 is attached to lid 20 by means of thermal material 95. Thermal interface gap 40 between semiconductor die 70 and lid 20 is preferably characterized by a substantially uniform thickness. Substrate 30 typically includes one or more vias, and may also have mounted thereon other discrete components such as chips, capacitors, resistors and the like. An optional underfill material may also be applied to solder balls 80, substrate pads 35 and/or other device interconnects to enhance solder joint fatigue life. Lid 20 may be fabricated from any suitable material capable of withstanding the mechanical and thermal loads applied thereto, such as a metal, a metal alloy, aluminum, anodized aluminum, KOVAR or copper.

In a preferred embodiment of the present invention, thermal interface layer 65 comprises a suitable thermal material 50 having spherical inclusions 60 suspended therein. DOW CORNING™ high-temperature epoxy DC3-6265 HP has been found to be particularly efficacious for use as thermal interface material 50 of the present invention, with spherical inclusions 60 formed from silicon suspended therein. Optimally, loading of spherical inclusions 60 in such thermal material 50 ranges between about 1% by volume and about 10% by volume of the thermal material, with about 5% by volume of the thermal material being the most preferred. Spherical inclusions 60 preferably have a diameter ranging between about 25 μm and about 75 μm, with about 45 μm being preferred in the presently described embodiment.

Continuing to refer to FIG. 1, it will be seen that spherical inclusions 60 are preferably of at least one substantially uniform diameter, where the largest of the substantially uniform diameter spherical inclusions employed will dictate the thickness of thermal interface gap 40. Accordingly, the thickness of gap 40 may be selected by choosing spherical inclusions 60 of one or more appropriate desired diameters, where the largest such diameter will determine the thickness of interface gap 40.

During the manufacturing process, thermal material 50 loaded with spherical inclusions 60 is dispensed atop semiconductor die 70, and lid 20 is placed thereon. A suitable mechanical load is then applied to lid 20 to cause thermal material 50 and spherical inclusions 60 suspended therein to be squeezed between lid 20 and die 70 until a layer of the largest-diameter spherical inclusions 60 is positioned therebetween. While any smaller-diameter spherical inclusions present in thermal material 50 will not dictate the thickness of interface gap 40, they may facilitate the process of the various-diameter spherical inclusions rolling over and past one another as the lid is compressed against the die and the thermal material and inclusions are squeezed therebetween.

When spherical inclusions 60 are formed from a relatively incompressible material such as glass, silicon, ceramic or metal, further compression of thermal material 50 becomes difficult or impossible owing to the presence of inclusions 60. Because spherical inclusions 60 are round, they slide past one another during compression to permit a layer of spheres to form in gap 40. When inclusions 60 are formed from a compressible material such as a suitable polymer, plastic or other material, compression of thermal material 50 must be carefully controlled to prevent spherical inclusions 60 from being too greatly compressed between lid 20 and die 70.

Once having been uniformly mixed in thermal material or other suitable thermal material matrix 50, spherical inclusions 60 of the present invention will generally remain suspended and fairly evenly distributed throughout the matrix of thermal material 50 for at least a reasonable period of time.

As described above, spherical inclusions 60 are preferably formed from a relatively incompressible or incompressible material such as glass, ceramic or silver, but may also be formed from any suitable incompressible material such a metal, a metal alloy or a suitable polymer. In the case where a compressible or somewhat compressible material is employed to form spherical inclusions 60, such inclusions may be formed from any suitable material capable of withstanding the thermal and mechanical loads applied thereto, such as suitable polymer or synthetic material.

In one embodiment of the present invention, spherical inclusions 60 are formed from a material having high thermal conductivity, such as silver or another suitable metal or metal alloy. Heat generated by underlying semiconductor die 20 is transferred more quickly across thermal interface gap 40 when spherical inclusions 60 are formed from such a high thermal conductivity material and can help overcome the negative effects attending the typically low thermal conductivity of many materials otherwise suitable for use as thermal material 50. The thermal conductivity of thermal material 50 may be also increased by adding highly thermally conductive materials thereto, such as metal fillers or particles, or by employing a thermal material 50 that is specifically formulated to have high thermal conductivity.

In the presently described embodiments of the present invention, it has been discovered that the thickness of thermal interface gap 40 preferably ranges between about 25 μm and about 75 μm, with about 45 μm being preferred, such thickness being determined by the largest diameter selected for the spherical inclusions. Other diameters and thermal interface gap thicknesses may be employed successfully, however, and yet fall within the scope of the present invention.

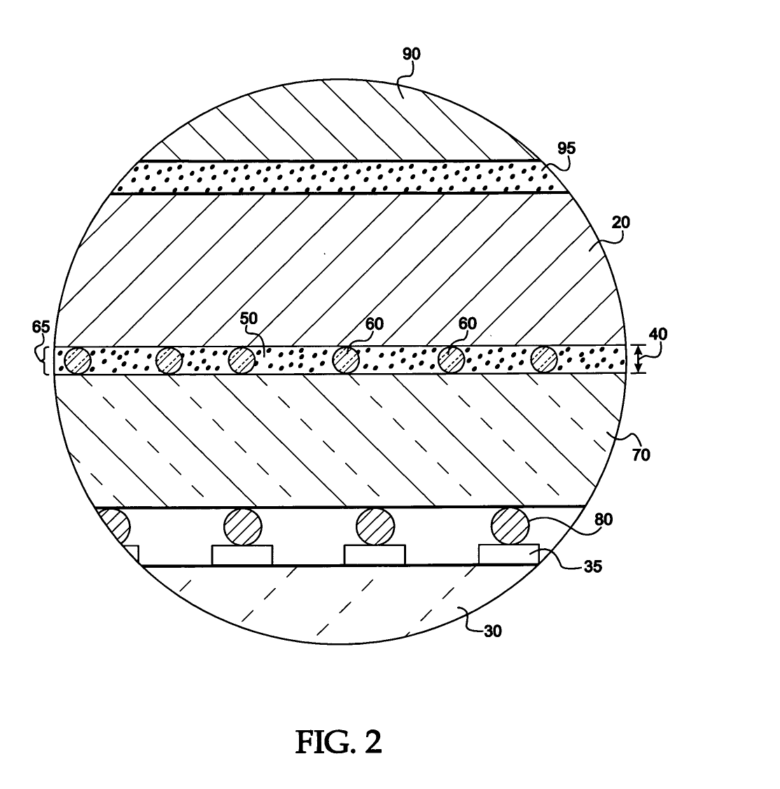

Referring now to FIG. 2, there is shown a close-up view of a portion of the semiconductor die package of FIG. 1 according to one embodiment of the present invention. Spherical inclusions 60 of FIG. 2 are formed of relatively incompressible silicon or glass and are disposed between lid 20 and semiconductor die 70. As shown in FIG. 2, thermal interface layer 65 comprises spherical inclusions 60 and thermal material 50. In a preferred embodiment of the present invention, thermal material 50 is a high-temperature epoxy that cured following compression of thermal material 50 and spherical inclusions 60 between lid 20 and semiconductor die 70. The largest diameter spherical inclusions 60 are preferably arrayed in a layer following such compression and curing.

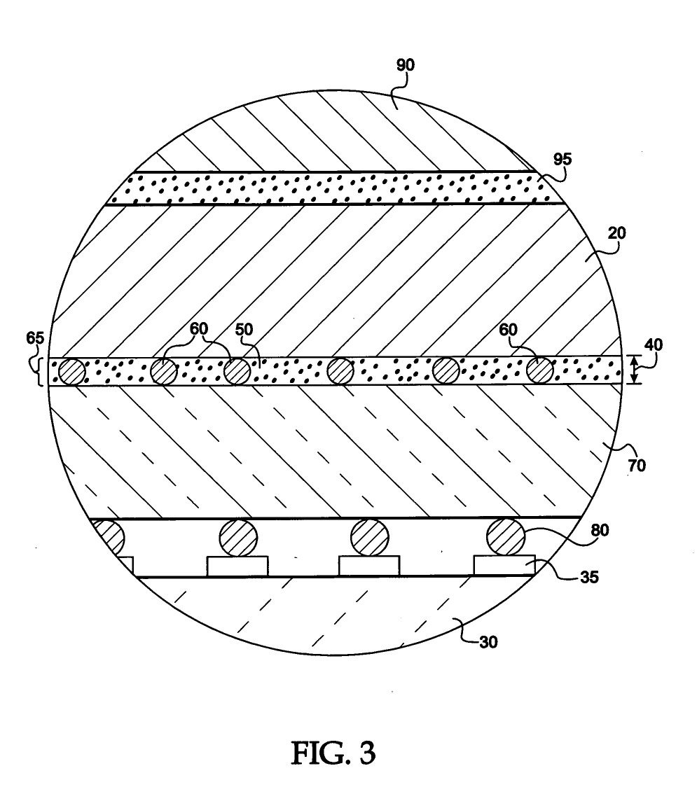

FIG. 3 shows a close-up view of a portion of the semiconductor die package of FIG. 1 according to another embodiment of the present invention. Spherical inclusions 60 of FIG. 3 are formed of relatively incompressible silver or another suitable metal or metal alloy, and are disposed between lid 20 and semiconductor die 70. As shown in FIG. 3, spherical inclusions 60 are surrounded by thermal material 50, which is preferably high-temperature epoxy that has been cured following compression of thermal material 50 and spherical inclusions 60 between lid 20 and semiconductor die 70. The largest diameter spherical inclusions 60 are arrayed in a layer following such compression and curing.

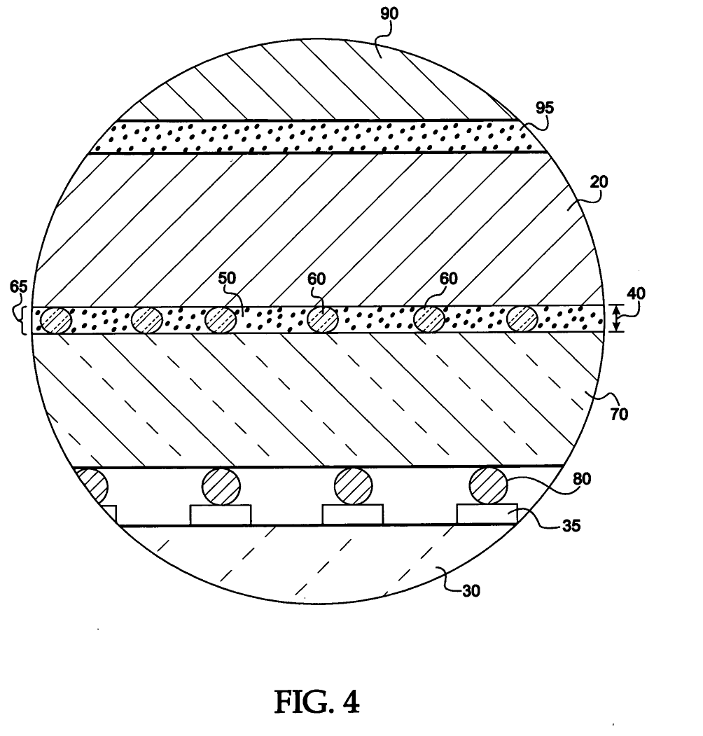

Referring now to FIG. 4, there is shown a close-up view of a portion of the semiconductor die package of FIG. 1 according to yet another embodiment of the present invention. Spherical inclusions 60 of FIG. 4 are formed of a relatively compressible suitable polymeric or other material capable of withstanding the thermal and mechanical loads to which interface 50 and inclusions 60 are subjected. As shown in FIG. 2, spherical inclusions 60 are disposed between and somewhat compressed by lid 20 and die 70. Inclusions 60 are surrounded by thermal material 50, which again is preferably (although not necessarily) a high-temperature epoxy that has been cured following compression of thermal material 50 and spherical inclusions 60 between lid 20 and semiconductor die 70. The largest diameter spherical inclusions 60 are also arrayed in a layer following such compression and curing.

Note that spherical inclusions 60 and thermal interface thicknesses 40 illustrated in FIGS. 1 through 4 are not necessarily drawn to scale owing to the very small sizes of inclusions 60 that are generally employed in actual practice. Inclusions 60 may be formed of glass, silicon, ceramic, a metal, a metal alloy, silver, gold, copper, a polymer, a polymeric substance, a plastic, or any other suitable material.

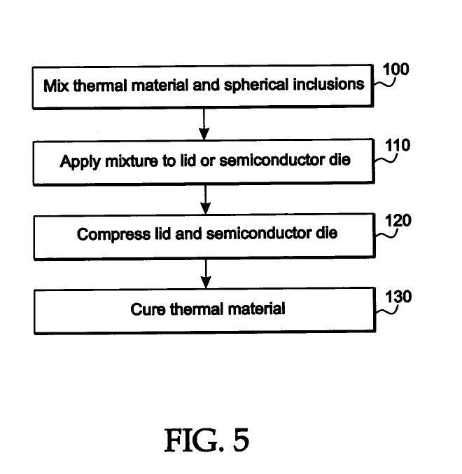

FIG. 5 illustrates a method according to one embodiment of the present invention. In step 100, a suitable thermal material or portion of a thermal material, such as the aforementioned high-temperature thermal material manufactured by DOW CORNING™, is loaded with the desired amount of spherical inclusions, and the inclusions are mixed therein until a substantially uniform suspension of such inclusions in the thermal material matrix has been obtained. Thereafter, the mixture of thermal material and spherical inclusions is dispensed or metered out onto the top of a semiconductor die 70 in a desired pattern. The bottom surface of lid 20 is then placed atop the metered or dispensed mixture of thermal material 50 and spherical inclusions 60 and die 70, and a mechanical load of sufficient magnitude and duration is applied thereto. The load is applied until spherical inclusions 60 form a layer of spheres disposed between lid 20 and die 70, and the upper and lower portions of such spheres engage and contact the upper and lower surfaces, respectively, of die 70 and lid 20. Next, semiconductor die package 20 is subjected to a high temperature environment ranging between about 125 degrees Centigrade and about 175 degrees Centigrade for a period of time ranging between about 20 minutes and about 40 minutes to cure thermal material 50. Of course, any number of suitable time/temperature profiles known in the art may be employed to cure thermal material or other thermal material 50.

Tests performed on working prototypes of one embodiment of semiconductor package 10 of the present invention yielded the results shown in Tables 1 and 2 below.

TABLE 1
Pull Data Obtained Using a Dispense Weight of 15 mg of
Thermal Material 50 for Each Die 70

| Test | Resulting Specifications |
|---|---|
| Bond Line | 25 um–75 um (thickness of the material |
| Thickness | between the top of die 70 and the bottom |
| | of lid 20) |
| Lid Tilt | 100 um max |
| Lid pull strength | 14 kgf min (pull on lid 20) |

TABLE 2
Environmental Data Obtained Using Packages 20 of Table 1

| Test | Test Method |
|---|---|
| Moisture Resistance (MRT) | JEDEC |
| Level 3, peak temp 220° C. - Passed | JESD22-A113-B |
| Temperature Cycle (TC) condition B, | JEDEC |
| −55° C. to 125° C., 1000 cycles - Passed | JESD22-A104-B |
| Highly Accelerated Stress Test (HAST), 130° C., | JEDEC |
| 85% RH, ~2 atm. Pressure, 96 hours, no bias - Passed | JESD22-A110-B |

The preceding specific embodiments are illustrative of the practice of the invention. It is to be understood, therefore, that other expedients known to those skilled in the art or disclosed herein may be employed without departing from the invention or the scope of the appended claims. For example, the present invention is not limited to the use of epoxy or adhesive for thermal material 50, and may be employed with a cured epoxies, cured adhesives, foams, plastics, thermoplastics, gels, polymer gels, crosslinked gels, polymers, crosslinked polymers and other suitable thermal materials suitable for forming thermal interface 50 and holding spherical inclusions 60 suspended therein prior to dispensing or metering such thermal material onto semiconductor die 70 or lid 20. As a further example, thermal interface 65 may be filled not only with an appropriate thermal material 50 and spherical inclusions 60 of a first diameter that corresponds to the thickness of gap 40, but may also comprise spherical inclusions of a second diameter that is less than the first diameter. Indeed, spherical inclusions of a range of diameters may be employed in gap 40 so long as a sufficient number of spherical inclusions of a first diameter are included in thermal material 50 to permit an accurate and even thickness of gap 40 between lid 20 and die 70 to obtain.

Having read and understood the present disclosure, those skilled in the art will now understand that many combinations, adaptations, variations and permutations of known thermal interface material, lid and semiconductor die systems, devices, components and methods may be employed successfully in the present invention.

In the claims, means plus function clauses are intended to cover the structures described herein as performing the recited function and their equivalents. Means plus function clauses in the claims are not intended to be limited to structural equivalents only, but are also intended to include structures which function equivalently in the environment of the claimed combination.

All printed publications and patents referenced hereinabove are hereby incorporated by referenced herein, each in its respective entirety.

I claim:

1. A semiconductor die package, comprising:
(a) a semiconductor die;
(b) a lid covering at least portions of the die, and
(c) a thermal material disposed between the die and the lid, the thermal material comprising spherical inclusions of at least a first substantially uniform diameter, the inclusions forming a layer of first-diameter spheres disposed between the die and the lid, the inclusions and the thermal material forming a thermal interface layer having a thickness.

2. The package of claim 1, further comprising a substrate upon which the semiconductor die is mounted.

3. The package of claim 1, wherein the lid, the thermal material and the inclusions are configured to conduct heat away from the semiconductor die.

4. The package of claim 1, wherein the thermal material comprises at least one of an epoxy, an adhesive, a cured epoxy, a cured adhesive, a foam, a plastic, a thermoplastic, a cured thermal material, a gel, a polymer gel, a crosslinked gel, a polymer and a crosslinked polymer.

5. The package of claim 1, wherein the spherical inclusions comprise at least one of glass, silicon, ceramic, a metal, a metal alloy, silver, gold, copper, a polymer, a polymeric substance, and a plastic.

6. The package of claim 1, wherein the spherical inclusions have diameters ranging between about 25 microns and about 75 microns.

7. The package of claim 1, wherein the thickness of the thermal interface layer ranges between about 25 microns and about 75 microns.

8. The package of claim 1, wherein the lid is formed from at least one of copper, silver, KOVAR, aluminum, anodized aluminum, a metal, and a metal alloy.

9. The package of claim 1, further comprising a heat sink attached to the lid.

10. The package of claim 1, wherein the spherical inclusions comprise between about 1% by volume of the thermal interface layer and about 10% by volume of the thermal interface layer.

11. A method of making a semiconductor die package, comprising assembling a semiconductor die and a lid with a thermal material comprising spherical inclusions of at least a first substantially uniform diameter disposed therebetween to form a thermal interface layer.

12. The method of claim 11, further comprising curing the thermal material.

13. The method of claim 11, further comprising cross-linking the thermal material.

14. The method of claim 11, further comprising compressing the thermal material and the inclusions between the lid and the die.

15. The method of claim 11, further comprising compressing the thermal material and the inclusions between the lid and the die until at least some of the inclusions engage both the lid and the die.

16. The method of claim 11, wherein the thickness of the thermal material and the inclusions disposed between the die and the lid ranges between about 25 microns and about 75 microns.

17. The method of claim 11, further comprising mounting the semiconductor die on a substrate.

18. The method of claim 11, wherein the semiconductor die is a flip chip mounted on a substrate.

19. The method of claim 11, further comprising mounting a heat sink to the lid.

20. The method of claim 11, wherein the semiconductor die is one of a central processing unit, a microprocessor, an ASIC, a controller and a processor.

21. The method of claim 11, wherein the spherical inclusions comprise between about 1% by volume of the thermal interface layer and about 10% by volume of the thermal interface layer.

22. A method of dissipating heat from a semiconductor die package, comprising transferring heat from a semiconductor die in a semiconductor die package to a lid in the package with a thermal interface layer disposed between the semiconductor die and the lid, wherein the thermal interface layer comprises spherical inclusions of at least a first substantially uniform diameter and the inclusions form a layer of first-diameter spheres between the die and the lid.

23. The method of claim 22, wherein the thermal interface layer further comprises a thermal material.

24. The method of claim 23, wherein the thermal interface material is at least one of an epoxy, an adhesive, a cured epoxy, a cured adhesive, a foam, a plastic, a thermoplastic, a cured thermal material, a gel, a polymer gel, a crosslinked gel, a polymer and a crosslinked polymer.
